(19) United States
(12) Patent Application Publication
(10) Pub. No.: US 2026/0173671 A1
(43) Pub. Date: Jun. 18, 2026

(54) DISPLAY APPARATUS

(71) Applicant: LG Display Co., Ltd., Seoul (KR)

(72) Inventor: Seungryong JOUNG, Seoul (KR)

(73) Assignee: LG Display Co., Ltd., Seoul (KR)

(21) Appl. No.: 19/336,018

(22) Filed: Sep. 22, 2025

(30) Foreign Application Priority Data
Dec. 13, 2024 (KR) 10-2024-0186192

(51) Int. Cl. H10K 59/124; H10K 50/11; H10K 59/131; H10K 59/80

(52) U.S. Cl. CPC H10K 59/124; H10K 50/11; H10K 59/131; H10K 59/80521

(57) ABSTRACT

A display apparatus according to the present disclosure may include a substrate including a plurality of sub-pixels, an insulating layer disposed on the substrate, a first trench portion formed in the insulating layer between adjacent sub-pixels. A first electrode is disposed on the insulating layer, and an emission layer is disposed on the first electrode. The emission layer includes a second trench portion aligned with the first trench portion. A conductive structure is disposed within the second trench portion, and a second electrode is disposed on the emission layer and the conductive structure.

### CROSS-REFERENCE TO RELATED APPLICATION

The present application claims priority to Korean Patent Application No. 10-2024-0186192, filed December 13, 2024, the entire contents of which is incorporated herein for all purposes by this reference.

### BACKGROUND

### Technical Field

This disclosure relates to a display apparatus for displaying images.

### Description of the Related Art

Display apparatuses are applied to various electronic devices such as TVs, mobile phones, laptops, and tablets. To this end, a range of researches have been conducted to develop display apparatuses that are thinner, lighter, and have lower power consumption.

As the demand for head mounted displays (HMDs) including display apparatuses has increased recently, research on them has also increased. The head-mounted display is an image display apparatus employing a device in the form of eyeglasses or a helmet to form a focus close to a user’s eyes.

The head-mounted display can implement virtual reality (VR) or augmented reality (AR). The head-mounted display has the advantage of providing a user with a high level of immersion into the screen, making a 1-inch image look as if it is as large as 60-inch image. For this purpose, the head-mounted display requires a small display apparatus with ultra-high resolution to be applied therein.

### BRIEF SUMMARY

The disclosure relates to a high-resolution OLED display apparatus suitable for applications such as virtual reality and augmented reality. It includes a multilayer trench structure designed to address electrical and optical performance issues. A first trench is formed in the insulating layer between adjacent sub-pixels to suppress lateral leakage current, while a second trench is formed in the emission layer directly above the first. A conductive structure is positioned within the second trench to bridge the sub-pixels and ensure continuous electrical connection across the cathode electrode, thereby preventing defects such as dark spots.

The conductive structure makes contact with the cathode electrode and may be formed from a metal with high reflectivity to enhance light output and improve color purity. Its placement is supported by a specific trench geometry where a wider upper portion houses the conductive structure, and a narrower lower portion prevents it from dislodging. In some embodiments, a ferromagnetic pattern is included below the trench to attract and retain the conductive structure during fabrication, allowing for accurate and efficient placement using magnetic or mechanical techniques.

By filling the recessed area in the trench and reducing abrupt height differences, the conductive structure helps form a smoother surface for the encapsulation layer. This reduces the occurrence of seams that can lead to visible image distortion. Together, these structural features enhance brightness, color fidelity, and display reliability, and contribute to improved performance in compact, power-efficient display systems.

As the resolution of a display apparatus increases with the increasing number of sub-pixels included in the display apparatus, the spacing distance between the sub-pixels decreases.

The decreased spacing distance between sub-pixels may cause the occurrence of lateral leakage current (LLC) between the sub-pixels neighboring each other.

If such lateral leakage current occurs between the sub-pixels neighboring each other, unintended sub-pixels may also emit light, which may reduce the color reproducibility of the display apparatus.

A trench structure may be taken into account as one of the methods for preventing lateral leakage current from occurring in an organic light-emitting display apparatus. The trench structure may be disposed between the sub-pixels neighboring each other to block the occurrence of the lateral leakage current.

Meanwhile, the organic emission layer and the cathode electrode may be disposed after the trench structure has been disposed between the neighboring sub-pixels. However, there may occur such a problem as the cathode electrode may be disconnected in the course of being formed around and in the trench structure.

In this regard, the disconnection of the cathode electrode may cause the light-emitting element not to turn on, which may lead to a defect in the display panel. For example, there may occur a dark spot defect in which a pixel does not emit light.

In addition, there may arise such a problem as a seam occurrence in a structure in which an organic emission layer and a cathode electrode are laminated and an encapsulation layer is disposed, on a sub-pixel having a trench structure constructed therein. As described above, if the seam occurs in the encapsulation layer, image distortion or the like may be visually perceived by a user, which may reduce the immersion in the image.

In view of the above, the inventors of the present disclosure have invented, through various experiments, a display apparatus with a novel configuration capable of preventing display panel defects caused by disconnection of a cathode electrode.

In addition, an object to be accomplished according to an embodiment of the present disclosure is to provide a display apparatus in which the seam occurrence can be prevented in an encapsulation layer in a sub-pixel with a trench structure disposed therein.

The objects to be accomplished according to an embodiment of the present disclosure are not limited to the ones described above, and other objects and advantages of the present disclosure which are not mentioned can be understood from the following description, and will be more clearly understood from the embodiments of the present disclosure. Furthermore, it will be readily appreciated that the objects and advantages of the present disclosure can be realized by the means presented in the claims, and combinations thereof.

A display apparatus according to an embodiment of the present disclosure may include a substrate including a plurality of sub-pixels, an insulating layer disposed on the substrate, a first trench portion formed in the insulating layer so as to pass between adjacent ones of the plurality of sub-pixels, a first electrode disposed on the insulating layer, an emission layer disposed on the first electrode and including a second trench portion extending along the first trench portion, a conductive structure disposed on the second trench portion, and a second electrode disposed on the emission layer and the second trench portion on which the conductive structure is disposed.

According to an embodiment of the present disclosure, it is possible to prevent the lateral leakage current from occurring between the sub-pixels neighboring each other by means of the first trench portion formed to pass between the plurality of sub-pixels, and of the second trench portion overlapping with the first trench portion in an up and down direction.

Additionally, according to an embodiment of the present disclosure, it is possible to prevent the cathode electrode from being disconnected in the sub-pixels neighboring each other by means of the conductive structure disposed on the second trench portion.

In addition, according to an embodiment of the present disclosure, it is possible to prevent a seam from occurring in the encapsulation layer disposed on the second trench portion by means of the conductive structure disposed on the second trench portion.

Accordingly, according to an embodiment of the present disclosure, it is possible to prevent display panel defects which would otherwise occur due to the disconnection of the cathode electrode.

In addition, according to an embodiment of the present disclosure, since it is possible to prevent the occurrence of seam in the encapsulation layer, image distortion can be prevented, thereby providing excellent image information.

Accordingly, according to an embodiment of the present disclosure, high color reproducibility and high brightness of the display panel can be implemented, so that power consumption of the display apparatus can be reduced, thereby providing a low-power consumption display apparatus. In addition, according to an embodiment of the present disclosure, there is an effect of preventing brightness reduction and dark spot defects in which pixels do not emit light. Consequently, there is an advantage in that a user’s immersion in images can be enhanced, thus improving the reliability of the product.

The present disclosure may have other effects besides the aforementioned ones, which are clearly recognizable to a person skilled in the art from the description below.

### BRIEF DESCRIPTION OF THE SEVERAL VIEWS OF THE DRAWINGS

FIG. 1 is a schematic plan view of a display apparatus;

FIG. 2 is a plan view of some of a plurality of pixels according to an embodiment;

FIG. 3 is a view showing a second trench portion disposed among adjacent sub-pixels;

FIG. 4 is a cross-sectional view taken along line I-I′ in FIG. 2;

FIG. 5 is an enlarged cross-sectional view of area III in FIG. 4;

FIG. 6 is a plan view of some of a plurality of pixels according to another embodiment;

FIGS. 7 to 10 are views showing second trench portions disposed between adjacent sub-pixels according to various embodiments;

FIGS. 11 to 13 are views illustrating processes of disposing a conductive structure according to various embodiments;

FIGS. 14 and 15 are views illustrating a process of disposing a conductive structure according to another embodiment; and

FIGS. 16 to 21 are views showing conductive structures disposed at a second trench portion according to the shape in which the sub-pixels are arranged.

### DETAILED DESCRIPTION

Advantages and features of the present disclosure, and a method of achieving the advantages and features will become apparent when referring to the following embodiments described later in detail together with the accompanying drawings. However, the present disclosure is not limited to the embodiments as disclosed below, but may be embodied in various different forms. Thus, these embodiments are set forth only to make the present disclosure complete, and to completely inform the scope of the present disclosure to those of ordinary skill in the technical field to which the present disclosure belongs.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the detailed description, like reference symbols refer to like components. Further, in describing the present disclosure, if it is determined that a detailed description of a related known technology may unnecessarily obscure the gist of the present disclosure, the detailed description thereof will be omitted. When the terms “comprise”, “include”, “have”, “be configured with”, “be comprised of”, and the like are used in the present disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “next to”, and the like, one or more other elements may be interposed between the two elements unless “just”, “directly”, or “close” is used.

To further elaborate, when a first element or layer is described as being “on” a second element or layer, the first element or layer may be disposed directly on the second, or indirectly on the second with one or more intervening elements or layers therebetween.

In describing a temporal relationship, for example, when the temporal order is described as “after”, “subsequent”, “next”, “before”, and the like, the case which is not continuous may also be included unless the term “just” or “directly” is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

It will be understood that, although the terms “first”, “second”, etc., may be used herein to describe various elements, these elements should not be limited by these terms. These terms are merely used to distinguish one element from another element. So, a first element referred to in the following description may represent a second element, without departing from the scope of the technical idea of the present disclosure.

Expressions such as “at least one of” preceding a list of elements may be interpreted to modify the entire list rather than each individual element. Furthermore, numerical values disclosed herein may be subject to variations or tolerances, even in the absence of an explicit statement to that effect.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, a display apparatus according to each embodiment of this disclosure will be described with reference to the accompanying drawings. The display apparatus 1 described below is, by way of example, an organic light-emitting diode display apparatus; however, this is not exhaustive.

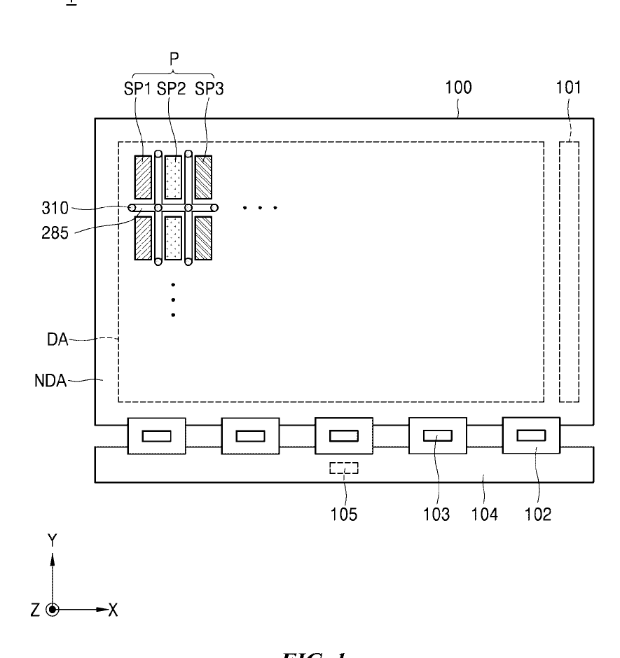

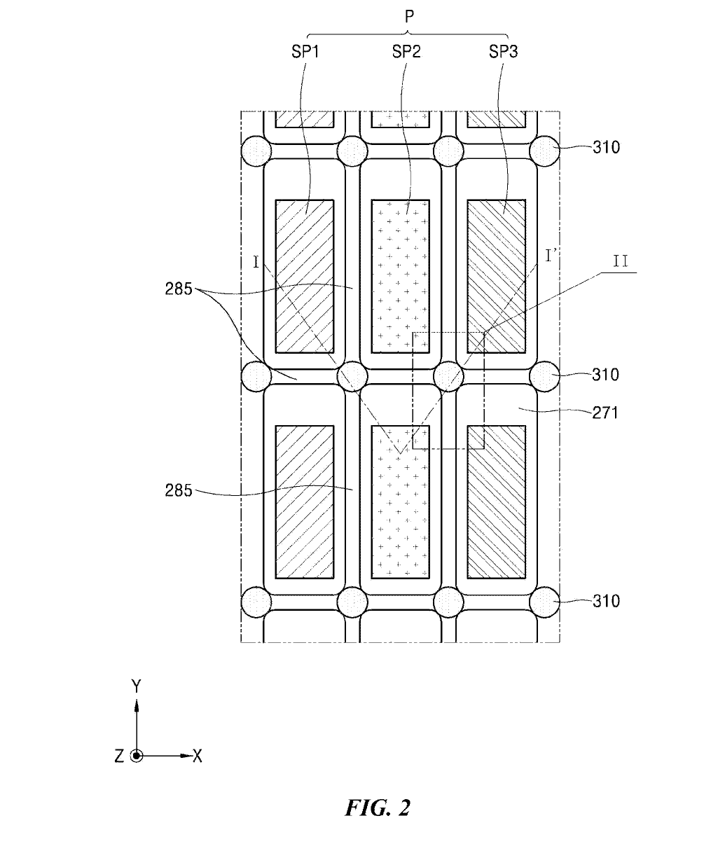

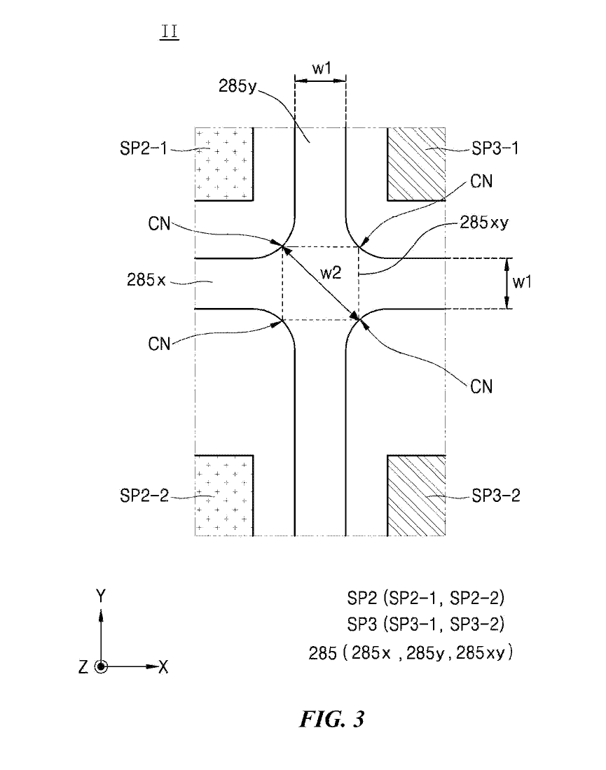

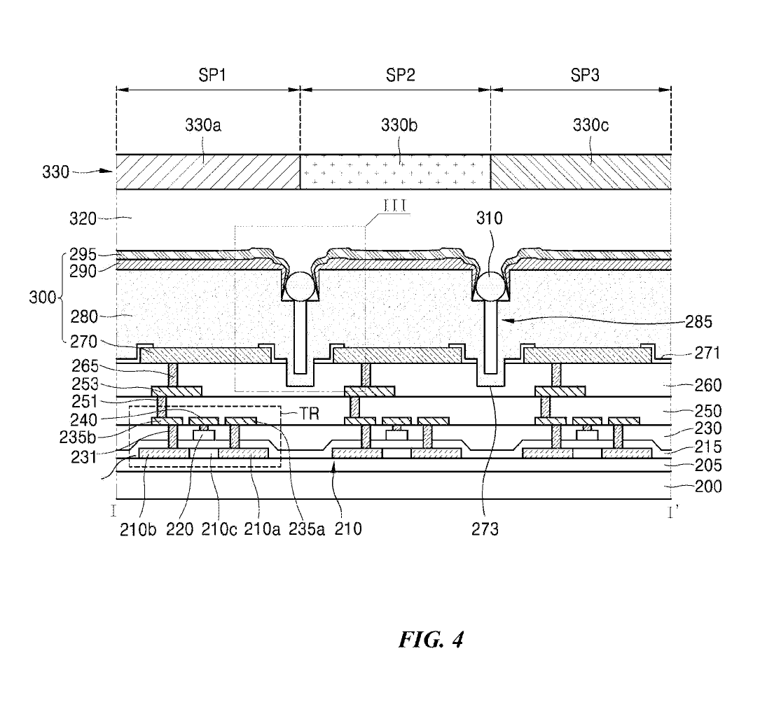

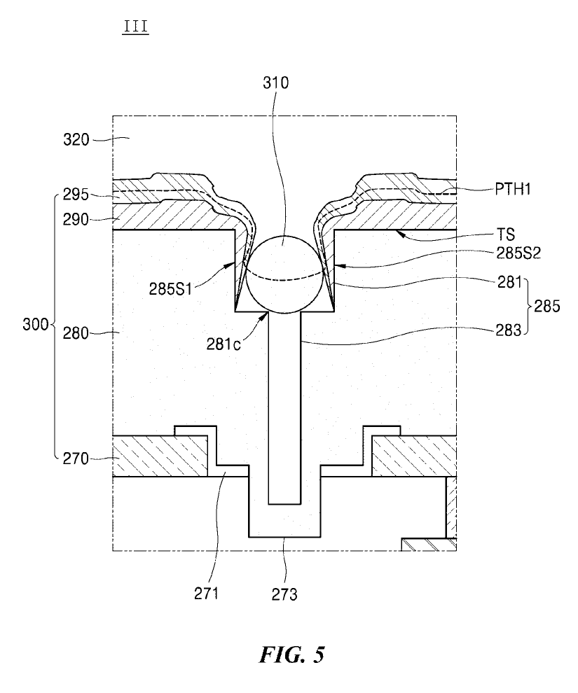

FIG. 1 is a schematic plan view of a display apparatus. FIG. 2 is a plan view of some of a plurality of pixels according to an embodiment. FIG. 3 is a view showing a second trench portion disposed among adjacent sub-pixels. FIG. 4 is a cross-sectional view taken along line I-I′ in FIG. 2. And FIG. 5 is an enlarged cross-sectional view of area III in FIG. 4. For convenience of explanation, in FIG. 2, there are shown only a bank 271, a second trench portion 285, and a conductive structure 310. For convenience of explanation, in FIG. 3, illustration of the conductive structure 310 is omitted.

Referring to FIGS. 1 to 3, a display apparatus 1 according to an embodiment of the present disclosure may include a display panel 100 having a display area DA and a non-display area NDA located outside the display area DA.

The display area DA may be an area where an image is displayed. The non-display area NDA may be an area where no image is displayed. The non-display area NDA may be located in the peripheral area (or border area) of the display panel 100; however, this is not exhaustive. For example, the remaining portion of the display area DA except an emission area from which light is emitted to the outside may be referred to as the non-display area NDA.

In the display area DA a plurality of pixels P may be disposed. Through the plurality of pixels P in the display area DA, an image can be displayed. In the non-display area NDA, there may be disposed various wirings and circuits for driving the plurality of pixels P in the display area DA. For example, in the non-display area NDA, there may be disposed driving circuits including a gate driving circuit and a data driving circuit. In the non-display area NDA, there may be disposed several drivers 101 for driving the display area DA. For example, the driver 101 may include, but is not limited to, a gate driver and a data driver.

In at least one side edge of the non-display area NDA a flexible circuit board 102 and a printed circuit board 104 may be disposed. For example, a plurality of flexible circuit boards 102 may be disposed; however, this is not exhaustive. On the flexible circuit board 102 an integrated circuit chip 103 may be disposed. The flexible circuit board 102 may be coupled with the display panel 100 at one side, and with the printed circuit board 104 at the other side, so that powers and signals for driving light-emitting elements supplied from the printed circuit board 104 can be provided to the display area DA of the display panel 100. For example, a signal for driving a light-emitting element may include a high-potential voltage, a low-potential voltage, a scan signal, a data signal, or the like.

The printed circuit board 104 may supply signals to the integrated circuit chip 103 disposed on the flexible circuit board 102. On the printed circuit board 104, there may be disposed various components for supplying various signals to the integrated circuit chip 103. For example, on the printed circuit board 104, there may be included a timing controller 105.

Each of the plurality of pixels P of the display area DA may be constituted with a plurality of sub-pixels SP1, SP2, SP3. Each of the sub-pixels SP1, SP2, SP3 may be formed in a respective one of areas defined by the intersection of a plurality of data wires extending in a first direction with a plurality of gate wires extending in a second direction intersecting with the first direction.

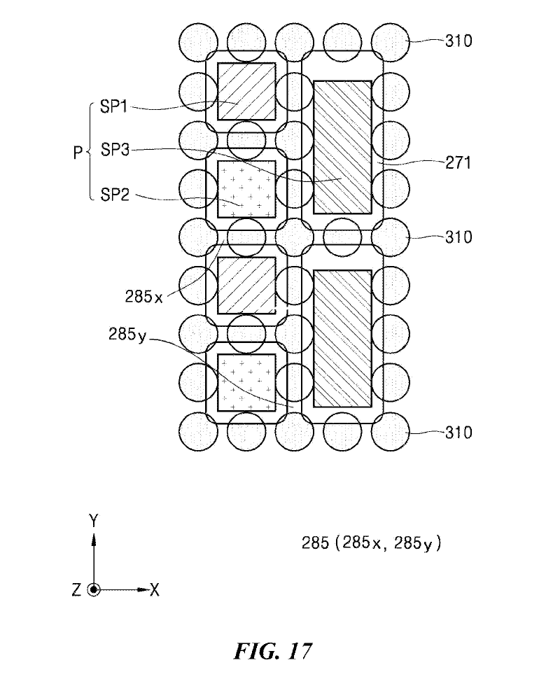

The plurality of sub-pixels SP1, SP2, SP3 may be disposed in an array on the display area DA. In an example, a plurality of sub-pixels SP1, SP2, SP3 may be spaced apart from each other in a first direction of the display area DA and a second direction intersecting with the first direction to be disposed in a matrix type array. The first direction may be a horizontal direction, an X-axis direction, or a row direction, while the second direction may be a vertical direction, a Y-axis direction, or a column direction. However, this is not exhaustive, and the arrangement shape, arrangement order, and arrangement direction of the sub-pixels SP1, SP2, SP3 may be changed in various ways. This will be described later in further detail with reference to FIGS. 17 to 21.

This disclosure describes an embodiment in which one pixel P is configured with the first sub-pixel SP1, the second sub-pixel SP2, and the third sub-pixel SP3; however, this is not exhaustive. For example, the one pixel P may further include additional sub-pixels.

The sub-pixels SP1, SP2, SP3 may each be implemented to emit light of the same color, such as white light, for every sub-pixel, or may each be implemented to emit light of different colors, such as red, green, or blue light, for every sub-pixel. In the following, an embodiment will be described in which the first sub-pixel SP1 is implemented to emit red light, the second sub-pixel SP2 is implemented to emit green light, and the third sub-pixel SP3 is implemented to emit blue light.

Meanwhile, between the respective sub-pixels, there may be disposed a first trench portion not shown, the second trench portion 285, and the conductive structure 310 formed at the second trench portion 285. The first trench portion may be disposed to overlap with the second trench portion 285 in an up and down direction. The first trench portion will be described later with reference to FIG. 4.

Referring to FIGS. 2 and 3, the plurality of sub-pixels SP1, SP2, SP3 may be disposed in an array on the display area DA. In an example, sub-pixels emitting light of the same color may be disposed in the same column. In an example, sub-pixels emitting light of different colors may be disposed alternately in the same row. For example, the first sub-pixels SP1 may each be arranged in the same column while being spaced apart from each other. For example, the second sub-pixels SP2 may each be arranged in the same column while being spaced apart from each other. For example, the third sub-pixels SP3 may each be arranged in the same column while being spaced apart from each other. Additionally, the first sub-pixel SP1, the second sub-pixel SP2, and the third sub-pixel SP3 may be disposed alternately in the same row direction.

The second trench portion 285 may be disposed in a boundary area distinguishing the respective sub-pixels from each other. The second trench portion 285 may be disposed to prevent lateral leakage current from occurring between the sub-pixels neighboring each other. The second trench portion 285 may be disposed within an emission layer.

The second trench portion 285 may include a first trench line 285x, a second trench line 285y, and an intersection area 285xy of the first trench line 285x and the second trench line 285y. The first trench line 285x may be disposed in a first direction (or X-axis direction) of the display area, and the second trench line 285y may be disposed in a second direction (or Y-axis direction) intersecting with the first direction. The first trench line 285x and the second trench line 285y may each have a size of the first width w1.

Meanwhile, the intersection area 285xy where the first trench line 285x and the second trench line 285y intersect each other may be implemented as an area having a greater width by the opposite corners CN of adjacent sub-pixels SP2-1, SP2-2, SP3-1, SP3-2. For example, the intersection area 285xy where the first trench line 285x and the second trench line 285y intersect each other may be implemented as a second width w2 greater than the first width w1. As the intersection area 285xy is implemented as the relatively greater second width w2, the second electrode, which is a common electrode, may be broken in continuity in the intersection area 285xy, leading to a disconnection.

If the disconnection occurs, pixel defects such as dark spots would occur because the second electrode needs to be formed to have continuity across the entire surface of the substrate so that it can be commonly connected to the emission layer formed in all pixels P. Additionally, there may occur a problem of seam formation in the structure in which the encapsulation layer is disposed after forming the second trench portion 285.

Considering the above, the conductive structure 310 may be disposed at least in the intersection area 285xy, as shown in FIG. 2. The conductive structure 310 may function to maintain contact with the second electrode, thereby preventing the occurrence of disconnection caused by a break in the continuity of the second electrode at the intersection area 285xy. Additionally, the step by the second trench portion 285 can be alleviated by the conductive structure 310. Thereby, it is possible to prevent the occurrence of seam in the encapsulation layer disposed on the second trench portion 285. As a result, it is possible to prevent the image distortion caused by the seam, and thus the degradation of immersion into the image.

Hereinafter, the detailed description will be provided, by way of example, but not exhaustively, based on an OLEDoS (OLED on Si wafer) structure in which a circuit portion including a complementary metal oxide semiconductor (CMOS) transistor TR is disposed on a substrate 200 which is a silicon wafer and an organic light-emitting element 300 is disposed on the circuit portion.

Referring to FIGS. 4 and 5, a plurality of transistors TR may be disposed on the substrate 200. The substrate 200 may include, but is not limited to, a silicon wafer, or may be a wafer formed of various semiconductor materials. Alternatively, the substrate 200 may include glass or a plastic film.

On the substrate 200 a buffer layer 205 may be disposed. The buffer layer 205 can prevent moisture or impurities from penetrating from the substrate 200 toward the transistor TR. The buffer layer 205 may be disposed in a single-layer or multilayer structure formed of an inorganic insulating material such as silicon oxide (SiOx), silicon nitride (SiNx) or the like.

The transistor TR may be disposed on the buffer layer 205. The transistor TR may include a semiconductor layer 210, a gate electrode 220, a source electrode 235a, and a drain electrode 235b.

On the buffer layer 205 a semiconductor layer 210 may be disposed. The semiconductor layer 210 may be comprised of an oxide semiconductor or a silicon-based semiconductor material. For example, the semiconductor layer may include a transparent oxide semiconductor material such as indium-gallium-zinc-oxide (IGZO) or indium-zinc-oxide (IZO). Additionally, the semiconductor layer may include a polysilicon semiconductor material.

The semiconductor layer 210 may include a source region 210a, a drain region 210b, and a channel region 210c. The gate electrode 220 may be disposed to overlap with the channel region 210c in an up and down direction. Between the gate electrode 220 and the semiconductor layer 210 a gate insulating layer 215 may be disposed. The source region 210a and the drain region 210b may be disposed on the opposite sides of the channel region 210c, respectively. In another example, the source region 210a and the drain region 210b may be formed by doping impurities into the substrate 200 configured with a silicon wafer.

On the gate electrode 220 a passivation layer 230 may be disposed. On the passivation layer 230, there may be disposed a source electrode 235a and a drain electrode 235b respectively electrically connected to the source region 210a and the drain region 210b with the gate electrode 220 interposed therebetween. The source electrode 235a and the drain electrode 235b may be electrically connected to the source region 210a and the drain region 210b, respectively, through first via electrodes 231 penetrating through the passivation layer 230 and the gate insulating layer 215. In one example, on the passivation layer 230, there may be disposed a signal electrode 240 that transmits a signal to the gate electrode 220. The signal electrode 240 may be formed together with the source electrode 235a and the drain electrode 235b; however, this is not exhaustive. The passivation layer 230 may be configured with a single layer or multiple layers comprised of an inorganic insulating material such as silicon oxide (SiOx) or silicon nitride (SiNx); however, this is not exhaustive. The source electrode 235a, the drain electrode 235b, the signal electrode 240, and the gate electrode 220 may be comprised of metal material, and, for example, may be configured with a single layer or multiple layers comprised of material including one of chromium (Cr), aluminum (Al), silver (Ag), copper (Cu), magnesium (Mg), molybdenum (Mo), or titanium (Ti), or its alloy; however, this is not exhaustive.

On the passivation layer 230 a first insulating layer 250 may be disposed. On the first insulating layer 250, there may be disposed a connection wiring 253 which may be electrically connected to the drain electrode 235b through a second via electrode 251 penetrating through the first insulating layer 250. On the first insulating layer 250 a second insulating layer 260 may be disposed. The first insulating layer 250 and the second insulating layer 260 may include an organic insulating material such as epoxy resin or urethane resin.

On the second insulating layer 260 a first electrode 270 may be disposed. The first electrode 270 may include a transparent metal oxide. For example, the metal oxide may include indium tin oxide (ITO) or indium zinc oxide (IZO). The one surface of the first electrode 270 may be connected to the third via electrode 265. The third via electrode 265 may penetrate through the second insulating layer 260 to be connected to the connection wiring 253. Thereby, the first electrode 270 may be electrically connected to the drain electrode 235b of the transistor TR through the third via electrode 265, the connection wiring 253 and the second via electrode 251. The first electrode 270 may also be referred to as an anode electrode or pixel electrode.

On the first electrode 270 the bank 271 may be disposed. The bank 271 may be disposed to cover the edge of the first electrode 270. A portion of the bank 271 may extend to the second insulating layer 260. The upper surface of the first electrode 270 that is exposed without being covered by the bank 271 may become a light-emitting area. The bank 271 may be configured with a single layer or multiple layers of an insulating material comprised of an inorganic material such as silicon nitride (SiNx) or silicon oxide (SiOx); however, this is not exhaustive. The bank 271 may also be referred to as a fence.

Between adjacent sub-pixels a first trench portion 273 may be disposed. The first trench portion 273 may be formed by removing a part of the second insulating layer 260 in the thickness direction of the second insulating layer 260. The first trench portion 273 and the bank 271 may distinguish sub-pixels SP1, SP2, SP3 in the display area from each other. The first trench portion 273 may be disposed between the first sub-pixel SP1 and the second sub-pixel SP2. The first trench portion 273 may be disposed between the second sub-pixel SP2 and the third sub-pixel SP3.

The bank 271 may have a break in its continuity to be disconnected at the end of the first trench portion 273 disposed between the sub-pixels neighboring each other.

On the first electrode 270 an emission layer 280 may be disposed. The emission layer 280 may include an organic layer that emits white light. To this end, the emission layer 280 may include a tandem structure in which a plurality of stacks that generate light of different colors are laminated. For example, each stack among the plurality of stacks may include a hole transport layer (HTL), an organic emission layer (EML), an electron transport layer (ETL), a hole blocking layer (HBL), a hole injecting layer (HIL), an electron blocking layer (EBL), and an electron injecting layer (EIL). Between the laminated stacks a charge generation layer may be disposed. The charge generation layer may be disposed between the stacks laminated in an up and down direction, so that it can supply charges to the stack to control the charge balance.

The emission layer 280 may be disposed in the inside of the first trench portion 273 and in the uppers side of the first trench portion 273. The layers included in the emission layer 280 may be made of organic material.

The emission layer 280 may include the second trench portion 285. Referring to FIGS. 4 and 5, the second trench portion 285 may include a first portion 281 and a second portion 283.

The second trench portion 285 may be disposed to overlap with the first trench portion 273 in an up and down direction. The first portion 281, or a groove, of the second trench portion 285 may have a shape in which a space is disposed by removing some thickness concavely in the thickness direction of the emission layer 280. The first portion 281 may include opposite sidewalls and a bottom surface. The second portion 283 may be formed by removing the emission layer 280 from the bottom surface of the first portion 281 toward the place where the first trench portion 273 is disposed. The first portion 281 may be connected from the bottom surface to the sidewalls of the second portion 283 through corner portions 281c. When viewed in a cross-sectional view, the second portion 283 may have a pillar shape. In one example, the first portion 281 of the second trench portion 285 may have a relatively greater width than that of the second portion 283.

On the emission layer 280 including the second trench portion 285 a second electrode 290, 295 may be disposed. Thereby, the light-emitting element 300 may be constituted by including the first electrode 270, the emission layer 280, and the second electrode 290, 295.

The second electrode 290, 295 may include a second-first electrode 290 and a second-second electrode 295 disposed on the second-first electrode 290. The second-first electrode 290 and the second-second electrode 295 may be formed across the entire surface of the substrate 200 so as to be commonly connected to the emission layer 280 formed in all pixels P. Therefore, the second electrode 290, 295 may be referred to as a cathode electrode or a common electrode. The second-first electrode 290 of the second electrode 290, 295, which is disposed in the lower side, may include a semi-transparent conductive material. For example, For example, the second-first electrode 290 may be formed of a metal material such as magnesium (Mg), silver (Ag), or an alloy of magnesium (Mg) and silver (Ag). The second-second electrode 295 of the second electrode 290, 295, which is disposed in the upper side, may be comprised of a transparent conductive material. For example, the second-second electrode 295 may be comprised of a transparent conductive material such as indium tin oxide (ITO) or indium zinc oxide (IZO).

The second-first electrode 290 may be disposed to extend from the upper edge of the second trench portion 285 to the sidewall surface. When the second-first electrode 290 is disposed in the second trench portion 285, a portion of the second-first electrode 290 may have a break in its continuity between adjacent sub-pixels due to the inclined angle at which it extends from the upper edge of the second trench portion 285 to the sidewall surface. The second-second electrode 295 may be disposed on the second-first electrode 290. The second-second electrode 295 may be formed to conform to the shape of the second-first electrode 290. Thereby, the second-second electrode 295 may be formed to cover the second-first electrode 290 which has been disposed to extend from the upper edge of the second trench portion 285 to the sidewall surface. As a result, the second-second electrode 295 may have a shape that protrudes farther than the upper edge of the second trench portion 285.

The conductive structure 310 may be disposed within the first portion 281 of the second trench portion 285. In an example, the conductive structure 310 may be a conductive ball or a conductive particle. When the conductive structure 310 is a conductive ball, it may be formed by coating a polymer particle with an electrically conductive material such as gold (Au), nickel (Ni), or copper (Cu). Additionally, the conductive structure 310 may include a metal material having high reflectivity. For example, it may include aluminum (Al) or silver (Ag).

When the conductive structure 310 is a conductive ball, the diameter of the conductive ball may be relatively smaller than the width of the first portion 281 of the second trench portion 285. Additionally, the second portion 283 of the second trench portion 285 may have a width smaller than the diameter or width of the conductive structure 310 to prevent the conductive structure 310 from escaping in a downward direction.

The conductive structure 310 may be in contact with and electrically connected to the second-second electrode 295 disposed on the sidewall of the first portion 281 of the second trench portion 285. Thereby, the conductive structure 310 can prevent the second electrode 290, 295 from being disconnected in the intersection region 285xy (see FIG. 3) among the boundary areas of the sub-pixels neighboring each other, where the first trench line 285x (see FIG. 3) of the second trench portion 285 which extends in the first direction intersects with the second trench line 285y (see FIG. 3) of the second trench portion 285 which extends in the second direction intersecting with the first direction.

For example, referring to FIG. 5, the current path PTH1 of the second electrode 290, 295 may be connected from the upper surface at one side of the second trench portion 285 to the upper surface at another side of the second trench portion 285 through the conductive structure 310 disposed in the first portion 281 of the second trench portion 285. Thereby, the electrical connection of the second electrode 290, 295 in the second trench portion 295 can be prevented from being disconnected. By preventing the second electrode 290, 295 from being disconnected, it is possible to prevent the occurrence of a dark spot defect in which a pixel does not emit light.

Additionally, in the case where the conductive structure 310 is made of a metal material having a high reflectivity, light generated from the light-emitting element 300 can be reflected by the conductive structure 310 to the outside, thus leading to the increased amount of emitted light. As a result, the light extraction efficiency of the light-emitting element 300 can be improved. Further, since the conductive structure 310 is disposed in the boundary area between the respective sub-pixels, light can be reflected by the conductive structure 310 to the outside, thus preventing the color mixing between the neighboring sub-pixels. Furthermore, it is possible to reduce the sub-peak of the light generated from the light-emitting element 300, thus improving the color purity.

On the second electrode 290, 295 an encapsulation layer 320 may be disposed. The encapsulation layer 320 may cover the second-second electrode 295 and the conductive structure 310. The encapsulating layer 320 may be made of an inorganic material, an organic material, or a mixture of inorganic and organic materials, and configured in a single layer or multiple layers.

On the encapsulation layer 320 a color filter 330 may be disposed. For example, the color filter 330 may include a red first color filter 330a provided in the first sub-pixel SP1, a green second color filter 330b provided in the second sub-pixel SP2, and a blue third color filter 330c provided in the third sub-pixel SP3. Thereby, in the first sub-pixel SP1, the first color filter 330a can transmit only red light when the white light emitted from the emission layer 280 passes therethrough; in the second sub-pixel SP2, the second color filter 330b can transmit only green light when the white light emitted from the emission layer 280 passes therethrough; and in the third sub-pixel SP3, the third color filter 330c can transmit only blue light when the white light emitted from the emission layer 280 passes therethrough.

Hereinafter, detailed description will be provided with regard to another structure in which the conductive structure 310 is disposed in a display panel having such a laminated structure.

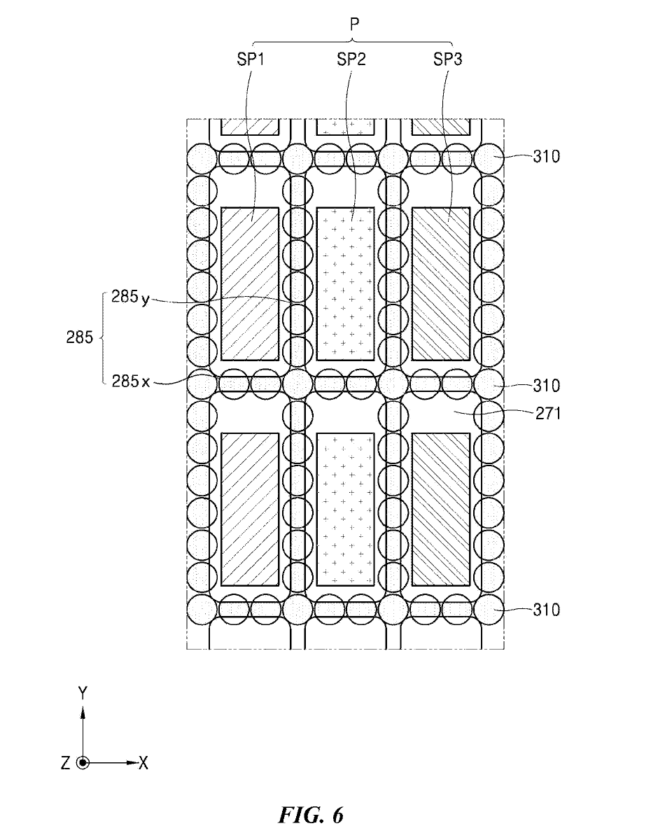

FIG. 6 is a plan view of some of a plurality of pixels according to another embodiment. Since FIG. 6 includes the same configuration as FIGS. 2 and 3 except for the arrangement positions of the conductive structures, any repetitive detailed description will be omitted or simplified, and differences therebetween will be discussed in detail. Identical reference symbols may denote identical components.

Referring to FIG. 6, a plurality of conductive structures 310 may be arranged to surround all the boundary areas between sub-pixels. For example, a plurality of conductive structures 310 may be disposed on the first trench line 285x of the second trench portion 285 among the boundary regions of neighboring sub-pixels which extends in a first direction and on the second trench line 285y of the second trench portion 285 among the boundary regions of neighboring sub-pixels which extends in a second direction intersecting with the first direction. Adjacent ones of the plurality of conductive structures 310 may be disposed to be spaced apart from each other by a predetermined distance. Alternatively, adjacent ones of the plurality of conductive structures 310 may be disposed to be in contact with each other. As the plurality of conductive structures 310 are arranged to surround all the boundary areas between the sub-pixels, the second electrode 290, 295 can stably maintain electrical continuity in the second trench portion 285.

Hereinafter, the second trench portions 285 having other shapes will be described.

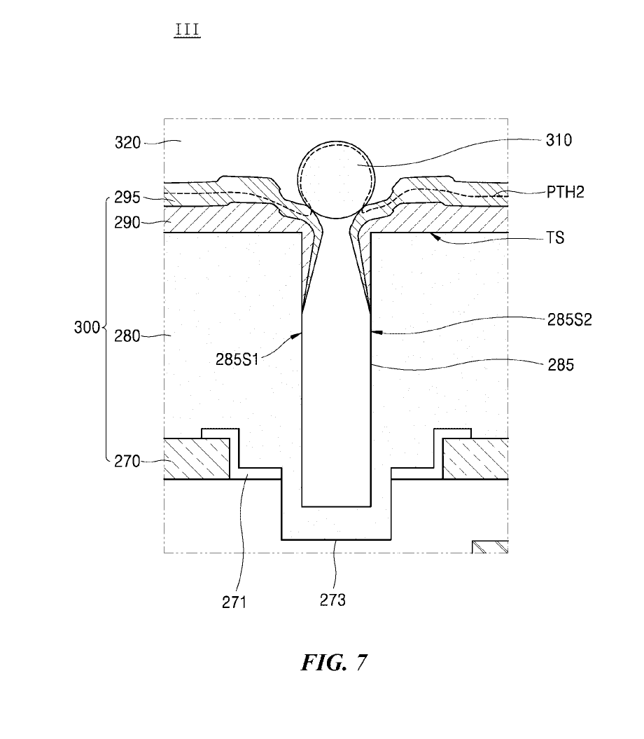

FIGS. 7 to 10 are views showing second trench portions disposed between adjacent sub-pixels according to various embodiments. Since FIGS. 7 to 10 include the same configuration as FIG. 5 except for the shape of the second trench portion, any repetitive detailed description will be omitted or simplified, and differences therebetween will be discussed in detail. Identical reference symbols may denote identical components.

Referring to FIG. 7, the second trench portion 285 disposed within the emission layer 280 may have the width of the bottom surface and the width of the upper open area which are the same in size. In this case, the bottom surface of the second trench portion 285 may be disposed toward the first trench portion 273. The second trench portion 285 may be disposed to overlap with the first trench portion 273 in an up and down direction. The second electrode 290, 295 may be disposed on the upper corner of the second trench portion 285 and the emission layer 280. The second-first electrode 290 and the second-second electrode 295 may be disposed at the upper corner of the second trench portion 285 to be laminated one above another. For example, on the first upper corner of the sub-pixel located at one side, the second-first electrode 290 and the second-second electrode 295 may be disposed to be sequentially stacked. In addition, on the second upper corner of the sub-pixel at another side neighboring the sub-pixel at one side, the second-first electrode 290 and the second-second electrode 295 may be disposed to be sequentially stacked. In this case, the second electrode 290, 295 on the first upper corner and the second electrode 290, 295 on the second upper corner may not be connected to each other, but spaced apart from each other by the first space.

The conductive structure 310 may be disposed on the second trench portion 285. The conductive structure 310 may be disposed in the first space between the second electrode 290, 295 on the first upper corner and the second electrode 290, 295 on the second upper corner. The width of the conductive structure 310 may be greater than the width of the first space. With this configuration, the conductive structure 310 may come into contact with the second-second electrode 295 of the second electrode 290, 295 to be electrically connected thereto. As a result, the current path PTH2 of the second electrode 290, 295 can be connected from the upper surface at one side of the second trench portion 285 to the upper surface at another side of the second trench portion 285 through the conductive structure 310 disposed in the first space of the second trench portion 285. Thereby, the electrical connection of the second electrode 290, 295 in the second trench portion 285 can be prevented from being disconnected.

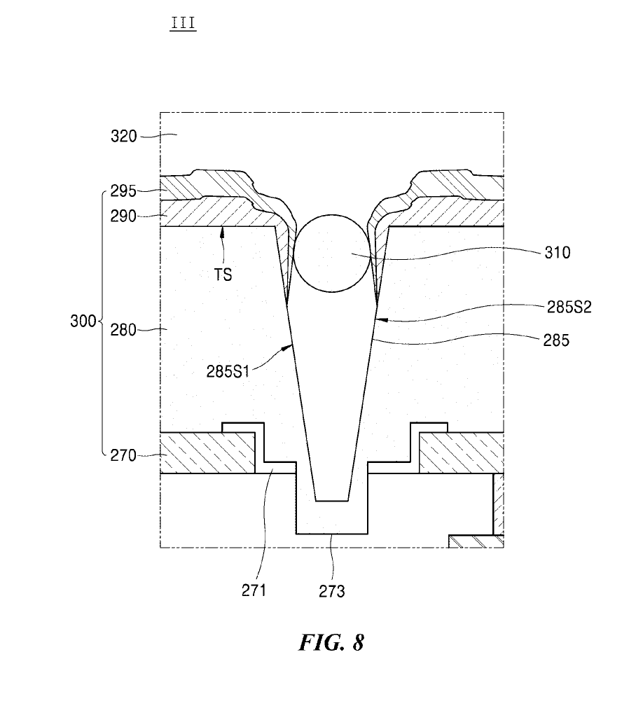

Referring to FIG. 8, the second trench portion 285 disposed within the emission layer 280 may be configured to have a width that decreases as it goes from the upper open area to the bottom surface. Thereby, the sidewall of the second trench portion 285 may be a inclined surface having a slope.

The second electrode 290, 295 may be disposed on the first upper corner of the second trench portion 285 disposed in the direction of the sub-pixel at one side. Additionally, the second electrode 290, 295 may be disposed on the second upper corner of the second trench portion 285 disposed in the direction of the sub-pixel at another side neighboring the sub-pixel at one side. In this case, the second electrode 290, 295 on the first upper corner and the second electrode 290, 295 on the second upper corner may not be connected to each other, but spaced apart from each other by the second space.

The conductive structure 310 may be disposed in the second space between the second electrode 290, 295 on the first upper corner and the second electrode 290, 295 on the second upper corner. The width of the conductive structure 310 may be greater than the width of the second space. With this configuration, the conductive structure 310 may come into contact with the second-second electrode 295 of the second electrode 290, 295 at its opposite side surfaces to be electrically connected thereto. Thereby, the electrical connection of the second electrode 290, 295 in the second trench portion 285 can be prevented from being disconnected.

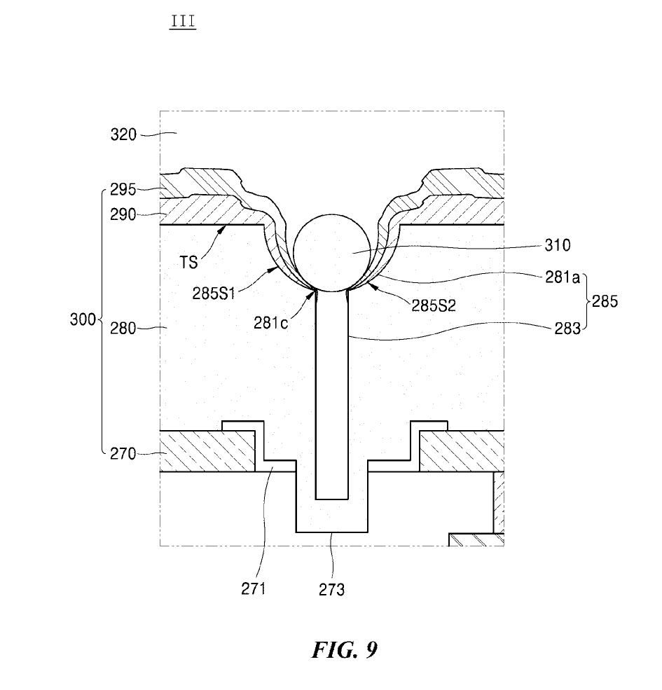

The second trench portion 285 according to FIG. 9 is different from the first portion 281 of the second trench portion 285 of FIG. 5 in that the first portion 281a of the second trench portion 285 has a concave lens shape. The second electrode 290, 295 may be disposed on the first portion 281a of the second trench portion 285 from the upper surface of the emission layer 280. Since the first portion 281a of the second trench portion 285 has the concave lens shape, the second electrode 290, 295 may be disposed on the first portion 281a along the surface of the concave lens shape.

The conductive structure 310 may be disposed in the second space between the second electrode 290, 295 on the first upper corner and the second electrode 290, 295 on the second upper corner. The width of the conductive structure 310 may be greater than the width of the second space. With this configuration, the conductive structure 310 may come into contact with the second-second electrode 295 of the second electrode 290, 295 at its opposite side surfaces to be electrically connected thereto. Thereby, the electrical connection of the second electrode 290, 295 in the second trench portion 295 can be prevented from being disconnected.

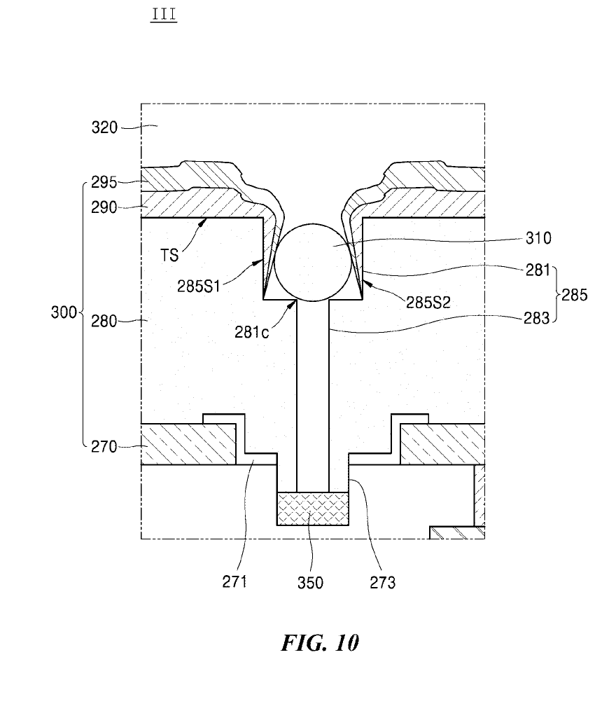

FIG. 10 is different from FIG. 5 in that a ferromagnetic pattern 350 is disposed within the first trench portion 273 overlapping with the second trench portion 285 in an up and down direction. The ferromagnetic pattern 350 may generate a magnetic field to attract the conductive structure 310 to the first portion 281 of the second trench portion 285. The ferromagnetic pattern 350 may be disposed to overlap with the bottom surface of the second portion 283 of the second trench portion 285. The ferromagnetic pattern 350 may include a ferromagnetic material such as iron, nickel, cobalt, iron oxide, chromium oxide, or ferrite.

The conductive structure 310 may be disposed within the first portion 281 of the second trench portion 285. The conductive structure 310 may come into contact with the second-second electrode 295 of the second electrode 290, 295 at its opposite side surfaces to be electrically connected thereto. Thereby, the electrical connection of the second electrode 290, 295 in the second trench portion 285 can be prevented from being disconnected. In addition, since the conductive structure 310 can be attracted and fixed to the first portion 281 of the second trench portion 285 by the ferromagnetic pattern 350, the electrical connection between the conductive structure 310 and the second electrode 290, 295 can be stably maintained.

Hereinafter, a method of disposing a conductive structure within the second trench portion 285 will be described.

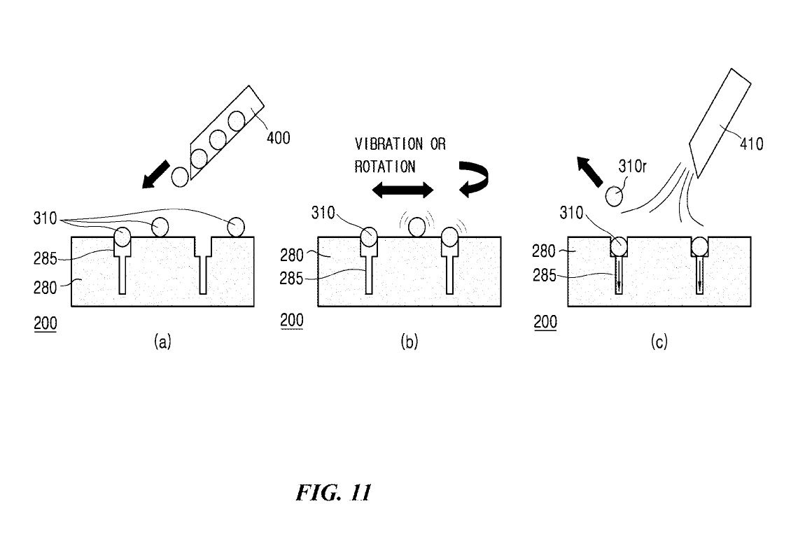

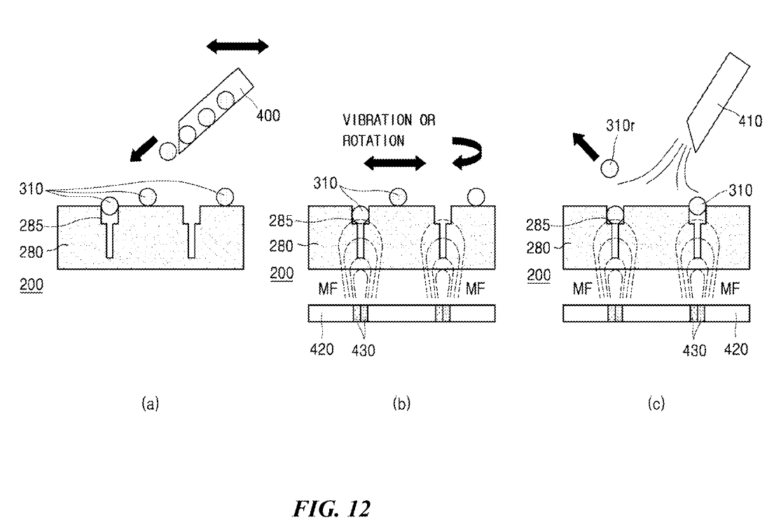

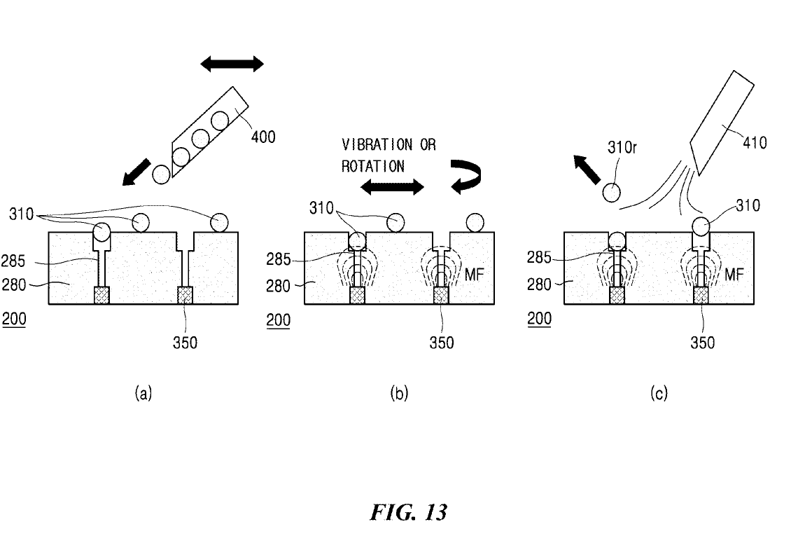

FIGS. 11 to 13 are views illustrating processes of disposing a conductive structure according to various embodiments. FIG. 11 is a method of fixing a conductive structure into a second trench portion using an air blower. FIG. 12 is a method of fixing a conductive structure into a second trench portion using a magnetic plate. And FIG. 13 is a method of fixing a conductive structure into a second trench portion using a ferromagnetic pattern.

Referring to FIG. 11, in the upper side of the substrate 200 an application device 400 of a conductive structure may be disposed. The substrate 200 may have a second electrode deposited on the second trench portion 285 of the emission layer 280. The application device 400 may include a multi-nozzle part capable of spraying the conductive structures 310. The conductive structure 310 may be a conductive ball.

Next, the conductive structures 310 are applied onto the substrate 200 from the application device 400 (FIG. 11(a)). The conductive structure 310 may be fixed to the first portion inside the second trench portion 285 by applying vibration to the substrate 200 or rotating the substrate 200 (FIG. 11(b)). At this time, a portion of the conductive structures 310 may be attracted into the second trench portion 285, and another portion thereof may remain on the substrate 200 where no second trench portion 285 is disposed. Thereby, it is possible to fix the position of the conductive structure 310 disposed in the second trench portion 285 with the use of an air blower 410, and the remaining conductive structure 310r can be removed (FIG. 11(c)). The air blower 410 may supply air at an oblique angle to the substrate 200. At this time, the conductive structure 310 disposed in the second trench portion 285 can be fixed in the second trench portion 285 by a force exerted thereon in the downward direction of the substrate 200 due to the air pressure, as indicated by a thin arrow. Thereby, the contact area with the second electrode 290, 295 within the second trench portion 285 can increase. And the remaining conductive structure 310r may be attracted into another second trench portion 285, or removed to the outside of the substrate 200.

Referring to FIG. 12, the conductive structures 310 are applied onto the substrate 200 through the application device 400 (FIG. 12(a)). The conductive structure 310 applied onto the substrate 200 may enter into the second trench portion 285, or be located in an area of the substrate 200 where no second trench portion 285 is disposed.

Next, the conductive structure 310 may be fixed to the first portion inside the second trench portion 285 (FIG. 12(b)). In this regard, a magnetic plate 420 may be disposed at a location spaced apart from the substrate 200. The magnetic plate 420 may include a magnetic pattern 430 disposed to correspond to the second trench portion 285 on the substrate 200. While applying a magnetic field MF from the magnetic plate 420 to the substrate 200, vibration may be applied to the substrate 200 or the substrate 200 may be rotated. Thus, the conductive structure 310 can be fixed to the first portion inside the second trench portion 285 by the magnetic field applied from the magnetic plate 420. The conductive structure 310 can be more easily fixed on the second trench portion 285 by the magnetic force between the magnetic pattern 430 of the magnetic plate 420 and the conductive structure 310.

Next, the remaining conductive structure 310r that is not fixed in the second trench portion 285 and remains on the substrate 200 may be removed using the air blower 410 (FIG. 12(c)).

Meanwhile, in order to further improve the fixing force of the conductive structure 310, the ferromagnetic pattern 350 may be further included on the substrate 200.

Referring to FIG. 13, the ferromagnetic pattern 350 may be disposed to overlap with the second trench portion 285 of the substrate 200. The ferromagnetic pattern 350 may be constituted before forming the second trench portion 285. For example, the ferromagnetic pattern 350 may be formed to overlap with the first trench portion 273 (see FIG. 10) before forming the emission layer 280 (see FIG. 10). The conductive structure 310 is applied through the application device 400 onto the substrate 200 with the ferromagnetic pattern 350 disposed therein (FIG. 13(a)). The conductive structure 310 applied onto the substrate 200 may enter into the second trench portion 285, or be located in an area of the substrate 200 where no second trench portion 285 is disposed.

Next, the conductive structure 310 may be fixed to the first portion inside the second trench portion 285 (FIG. 12(b)). The ferromagnetic pattern 350 can generate a magnetic field MF even without any external magnetic field. With this configuration, when applying vibration to the substrate 200 or rotating the substrate 200, the conductive structure 310 can be easily fixed to the second trench portion 285 due to the magnetic force exerted thereto by the ferromagnetic pattern 350.

The remaining conductive structure 310r that is not fixed in the second trench portion 285 and remains on the substrate 200 may be removed using the air blower 410 (FIG. 13(c)).

Hereinafter, detailed description will be provided with regard to a method of disposing a conductive structure 310 on a substrate in a state where the position of the conductive structure is pre-aligned with the position where the second trench portion 285 is disposed. In this case, since the position of the conductive structure 310 is pre-aligned, the number of process steps can be reduced.

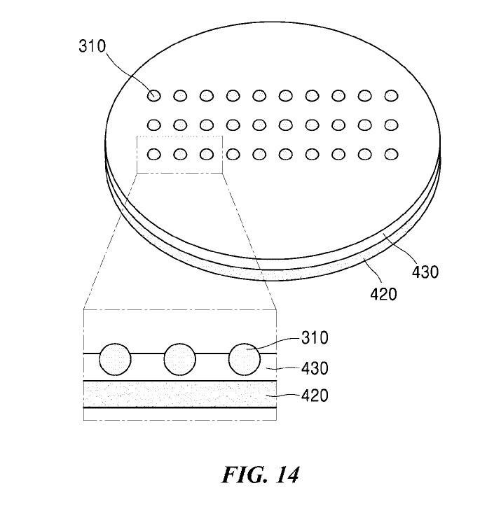

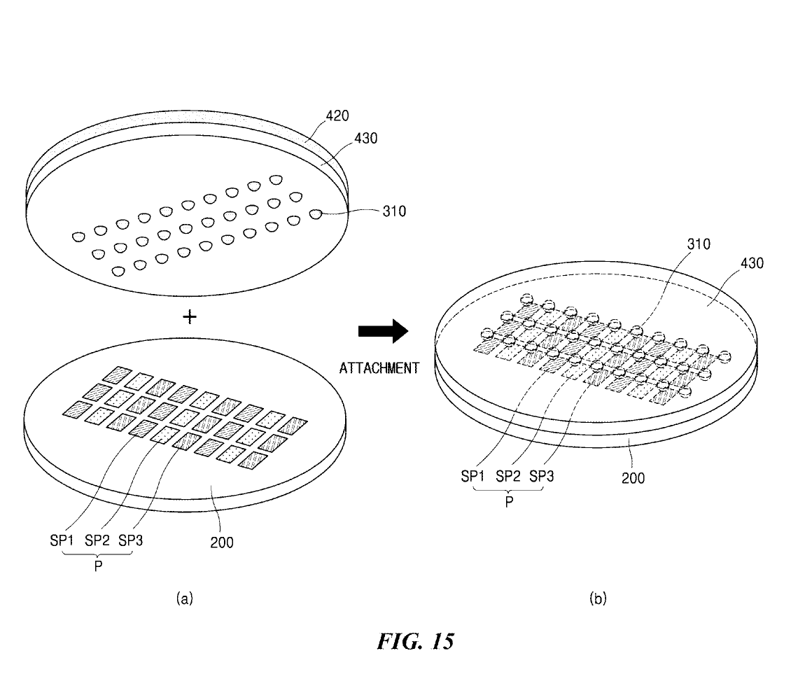

FIGS. 14 and 15 are views illustrating a process of disposing a conductive structure according to another embodiment.

Referring to FIG. 14, on a carrier substrate 420, there may be disposed a film 430 on which conductive structures 310 are disposed. The carrier substrate 420 may be a wafer or a glass substrate. The film 430 may include a resin material. For example, a plurality of conductive structures 310 may be arranged on the carrier substrate 420 to correspond to the positions where the second trench portions are disposed. And the plurality of conductive structures 310 may be fixed on the carrier substrate 420 through the film 430. The upper side surface portions of the plurality of conductive structures 310 may be exposed without being covered by the film 430.

Referring to FIG. 15, the substrate 200 and the carrier substrate 420 on which the conductive structures 310 are disposed may be disposed so as to face each other (FIG. 15(a)). The substrate 200 may have pixels P disposed thereon and including a plurality of sub-pixels SP1, SP2, SP3. In the respective boundary areas of the sub-pixels SP1, SP2, SP3 on the substrate 200, the second trench portions not shown may be disposed. At this time, the carrier substrate 420 may be disposed so that the exposed surface portions of the conductive structures 310 face the second trench portions of the substrate 200.

Next, the substrate 200 and the carrier substrate 420 on which the conductive structures 310 are disposed may be attached to each other to fix the conductive structures 310 to the second trench portions (FIG. 15(b)). And the carrier substrate 420 is removed. The carrier substrate 420 may be removed prior to the attachment step. The film 430 in which the conductive structures 310 are disposed may include a resin material, and thus function as an encapsulation layer. By employing the film 430 in which the conductive structures 310 are disposed, the process step for forming an encapsulation layer can be omitted.

Meanwhile, the sub-pixels may respectively be configured in various array shapes depending on a way of manufacturing a display apparatus.

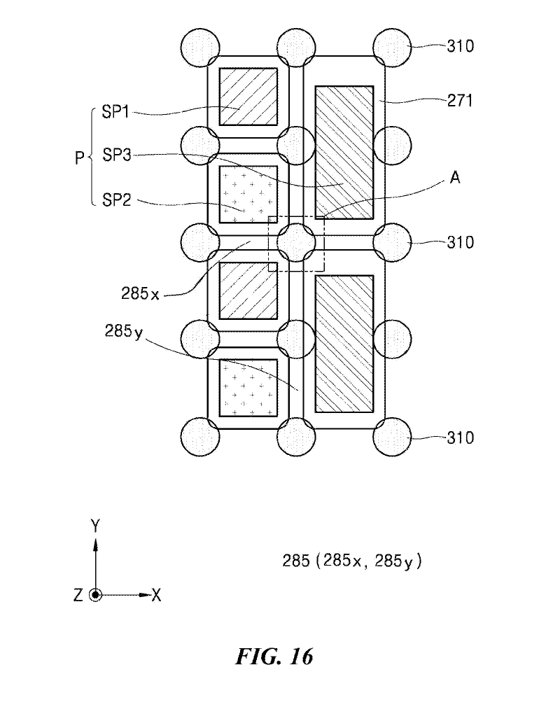

FIGS. 16 to 21 are views showing conductive structures disposed at a second trench portion according to the shape in which the sub-pixels are arranged. Since FIGS. 16 to 21 include the same configuration as FIG. 2 except for the shape in which the sub-pixels are arranged, differences therebetween will be discussed in detail. Identical reference symbols may denote identical components.

Referring to FIGS. 16 and 17, one pixel P may include a third sub-pixel SP3 disposed in a vertical direction (or Y-axis direction), which is the second direction of the display panel, a first sub-pixel SP1, and a second sub-pixel SP2, the first and second sub-pixels being disposed on one side of the third sub-pixel SP3. The first sub-pixel SP1 and the second sub-pixel SP2 may be disposed in the horizontal direction (or X-axis direction), which is the first direction of the display panel. The first sub-pixel SP1 and the second sub-pixel SP2 may be disposed in the same column. In one pixel P according to FIGS. 16 and 17, the third sub-pixel SP3 may have the largest surface area, and the first sub-pixel SP1 and the second sub-pixel SP2 may have smaller surface areas than that of the third sub-pixel SP3. The first sub-pixel SP1 and the second sub-pixel SP2 may have the same surface area; however, this is not exhaustive. For example, the first sub-pixel SP1 may be a red sub-pixel; the second sub-pixel SP2 may be a green sub-pixel; and the third sub-pixel SP3 may be a blue sub-pixel.

The conductive structure 310 may be disposed in an area A where the second trench portions 285 in the boundary areas of the respective sub-pixels intersect with each other. For example, the conductive structure 310 may be disposed in every area A where the first trench line 285x of the second trench portion 285 which is disposed in the first direction (or X-axis direction) of the display panel and the second trench line 285y of the second trench portion 285 which is disposed in the second direction (or Y-axis direction) intersect with each other.

Further, in the case where the plurality of conductive structures 310 are arranged to surround all the boundary areas between the sub-pixels as shown in FIG. 17, the second electrode 290, 295 can stably maintain electrical continuity in the second trench portion 285.

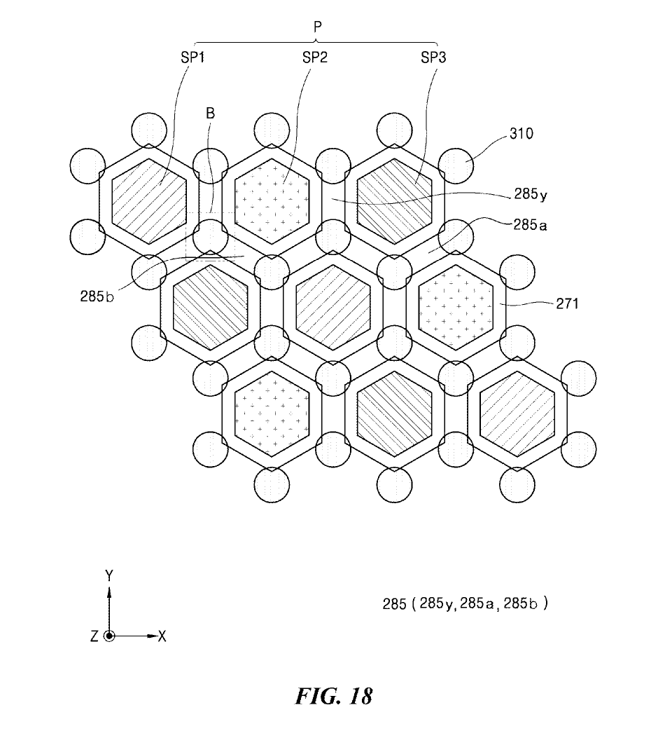

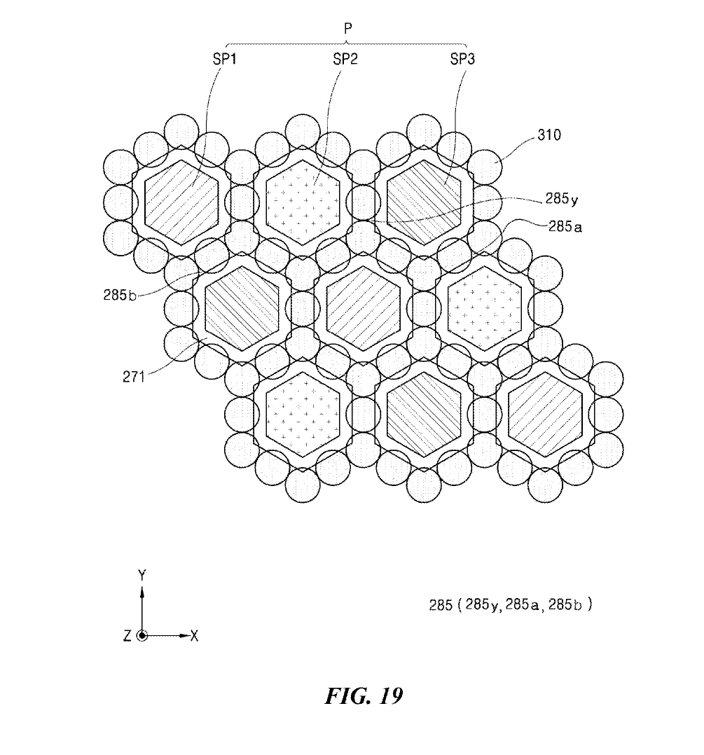

Referring to FIGS. 18 and 19, one pixel P may include a configuration in which a first sub-pixel SP1, a second sub-pixel SP2, and a third sub-pixel SP3 each have a regular polygonal shape, and are disposed to be spaced apart from each other. The first sub-pixel SP1, the second sub-pixel SP2, and the third sub-pixel SP3 may have a regular hexagonal shape. For example, the first sub-pixel SP1, the second sub-pixel SP2, and the third sub-pixel SP3 may be arranged in a triangular shape to be implemented as one pixel P.

The conductive structure 310 may be disposed in an area B where the second trench portions 285 in the boundary areas of the respective sub-pixels intersect with each other. For example, the conductive structure 310 may be disposed in every area B where the second trench line 285y of the second trench portion 285 which is disposed in the second direction (or Y-axis direction) of the display panel, a third trench line 285a of the second trench portion 285 which is disposed in a first inclined direction (a downward to the left direction), and a fourth trench line 285b of the second trench portion 285 which is disposed in a second inclined direction (a downward to the right direction) different from the first inclined direction intersect with each other.

Further, in the case where the plurality of conductive structures 310 are arranged to surround all the boundary areas between the sub-pixels as shown in FIG. 19, the second electrode 290, 295 can stably maintain electrical continuity in the second trench portion 285.

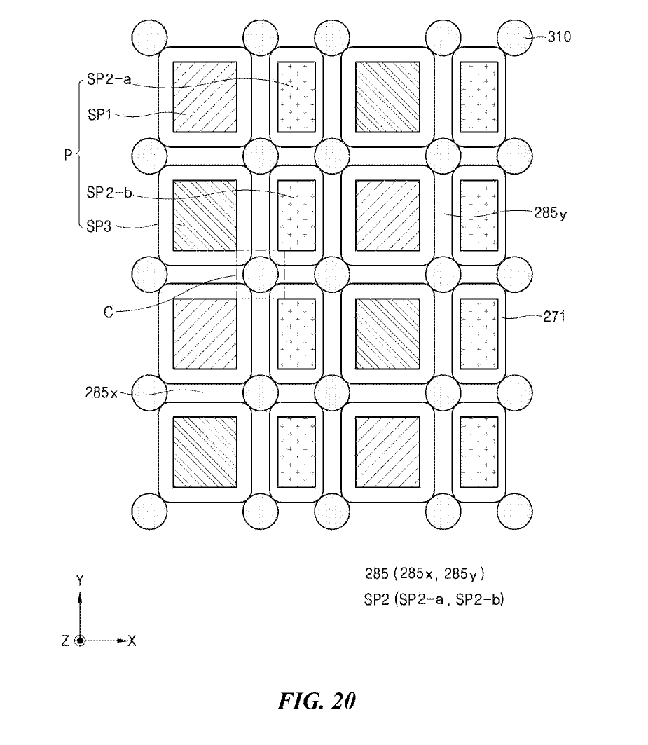

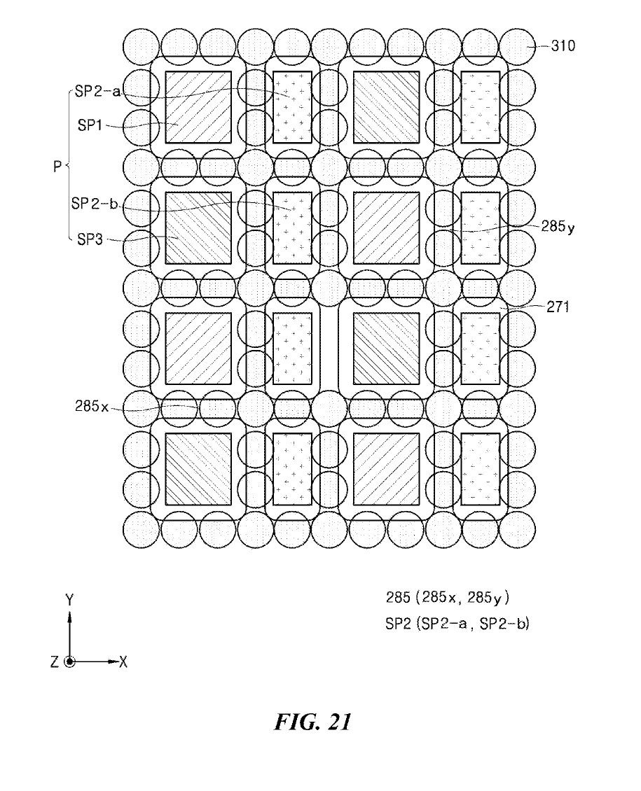

Referring to FIGS. 20 and 21, one pixel P may include a first sub-pixel SP1, a third sub-pixel SP3, the first and third sub-pixels being disposed to be spaced apart from each other in the vertical direction (or Y-axis direction), which is the second direction of the display panel, a second-first sub-pixel SP2-a disposed in one side of the first sub-pixel SP1 and spaced apart from the first sub-pixel SP1, and a second-second sub-pixel SP2-b disposed in one side of the third sub-pixel SP3 and spaced apart from the third sub-pixel SP3. The respective surface areas of the second-first sub-pixel SP2-a and the second-second sub-pixel SP2-b may be smaller than the respective surface areas of the first sub-pixel SP1 and the third sub-pixel SP3.

For example, the first sub-pixel SP1 may be a red sub-pixel; the second-first sub-pixel SP2-a and the second-second sub-pixel SP2-b may be green sub-pixels; and the third sub-pixel SP3 may be a blue sub-pixel.

The conductive structure 310 may be disposed in an area C where the second trench portions 285 in the boundary areas of the respective sub-pixels intersect with each other. For example, the conductive structure 310 may be disposed in every area C where the first trench line 285x of the second trench portion 285 which is disposed in the first direction (or X-axis direction) of the display panel and the second trench line 285y of the second trench portion 285 which is disposed in the second direction (or Y-axis direction) intersect with each other.

Further, in the case where the plurality of conductive structures 310 are arranged to surround all the boundary areas between the sub-pixels as shown in FIG. 21, the second electrode 290, 295 can stably maintain electrical continuity in the second trench portion 285.

The display apparatus according to various embodiments of the present disclosure may be described as follows.

A display apparatus according to an embodiment of the present disclosure may include a substrate configured to support a plurality of functional layers. An insulating layer may be disposed on the substrate and may serve to electrically isolate active components from underlying structures. A first trench portion 273 may extend into the insulating layer. The first trench portion 273 may be formed between adjacent sub-pixel regions and may serve as a feature to suppress lateral leakage current between sub-pixels, as well as provide structural delineation for subsequent processing steps.

A first electrode 270 may be formed adjacent to the first trench portion 273 and on the insulating layer (e.g., see FIG. 4). This first electrode 270 may function as an anode or pixel electrode in an organic light-emitting diode (OLED) structure and may be comprised of a transparent conductive material, such as indium tin oxide (ITO) or indium zinc oxide (IZO). An emission layer 280 may be disposed over the first electrode 270 and the insulating layer. The emission layer 280 may include one or more organic sub-layers such as a hole transport layer, an emissive layer, and an electron transport layer.

In this embodiment, a second trench portion 285 may extend into the emission layer 280 in a direction toward the substrate 200. The second trench portion 285 may be formed to overlap the first trench portion 273 in a plan view or vertical direction, although such alignment may vary based on design needs. A conductive structure 310 may be located to overlap with the second trench portion 285 in a plan view. The conductive structure 310 may be positioned to bridge or occupy at least part of the second trench portion 285 and may serve to improve electrical connectivity in regions where the emission layer topography introduces discontinuities. A second electrode 290, 295 may be disposed on the emission layer 280 and may extend over the second trench portion 285. The second electrode 290, 295 may be adjacent to or in electrical contact with the conductive structure 310, thereby enabling consistent cathodic continuity across the display panel.

In certain embodiments, the conductive structure 310 may be disposed directly within the second trench portion 285 and may be electrically connected to the second electrode 290, 295. The conductive structure 310 may contact the second electrode 290, 295 and may serve to ensure continuity across regions of topographical variance, particularly at trench intersections between sub-pixels.

In an example embodiment, the second trench portion 285 may be vertically aligned with the first trench portion 273. This vertical alignment may facilitate simplified fabrication and trench registration during multilayer processing. The alignment may also contribute to improved electrical isolation and structural coherence.

The conductive structure 310 may include a reflective metal material, such as aluminum, silver, or a silver-magnesium alloy, configured to enhance light extraction efficiency during display operation. The high reflectivity of the conductive structure 310 may help redirect internally emitted light toward the viewer-facing side of the display, thereby improving luminance and overall optical performance.

According to another embodiment, the second trench portion 285 may include a first portion 281 and a second portion 283. The first portion 281 may be wider and configured to accommodate the conductive structure 310, while the second portion 283, positioned between the first portion 281 and the substrate 200, may have a narrower width. The conductive structure 310 may be disposed within the first portion 281 and be situated above the second portion 283, thereby avoiding mechanical interference with underlying layers and facilitating easier placement or retention of the conductive structure during manufacture.

A ferromagnetic pattern 350 may also be provided within the first trench portion 273 and aligned to overlap with the conductive structure 310 in a plan view. During operation, the ferromagnetic pattern 350 may generate a magnetic field that attracts and retains the conductive structure 310 within the first portion 281of the second trench portion. This attraction may occur without the use of adhesives or other chemical bonding agents, thereby enabling simplified, clean, and reversible assembly processes.

In some configurations, the second trench portion 285 may include a first sidewall surface 285S1 and a second sidewall surface 285S2 facing one another. The second electrode 290, 295 may extend into the second trench portion 285 and make physical and electrical contact with at least one of the first sidewall surface 285S1 or second sidewall surface 285S2. The conductive structure 310 may be in direct contact with the second electrode at one or more points within the trench, thereby bridging across regions prone to electrical disconnection.

Further, at least one of the sidewall surfaces 285S1, 285S2 of the second trench portion 285 may be inclined, such that the lateral distance between opposing sidewalls decreases as the trench extends toward the substrate 200 (e.g., see FIGS. 8 and 9). This tapering profile may assist in the mechanical retention of the conductive structure and may also support conformal deposition of subsequent electrode layers.

In another embodiment, the second trench portion 285 may extend from a top surface TS of the emission layer 280 in a direction toward the substrate. The conductive structure 310 may be disposed such that at least a portion of the conductive structure protrudes above the top surface TS of the emission layer 280 (e.g., see FIGS. 8, 9). In alternate implementations, the conductive structure 310 may be disposed entirely below the top surface TS of the emission layer (e.g., see FIGS. 5, 10). In yet another variant, the conductive structure may protrude above the emission layer in its entirety (e.g., see FIG. 7). These positional configurations may be selected based on tradeoffs between electrical connectivity, optical performance, and layer stack height constraints.

The display apparatus may further include a plurality of sub-pixels disposed on the substrate. Each sub-pixel may correspond to a different color component, such as red, green, or blue, and the sub-pixels may be arranged in rows, columns, or other geometric patterns. A plurality of conductive structures may be disposed between adjacent sub-pixels. These conductive structures may be located within trench regions separating the sub-pixels and may serve to maintain electrical continuity across the second electrode or to mitigate color mixing and dark spot defects.

In one example, the plurality of sub-pixels may include sub-pixels having the same shape and size, and other sub-pixels having a different shape, a different size, or both (see FIGS. 2, 6, and 16-19). Such variation in sub-pixel geometry may be implemented to accommodate color-specific luminance balancing, human visual sensitivity, or design constraints related to pixel packing density. The placement and shape of the trench structures and conductive elements may likewise be adapted to support sub-pixel configurations of varying geometry.

A display apparatus according to further embodiments of the present disclosure may include a substrate including a plurality of sub-pixels, an insulating layer disposed on the substrate, a first trench portion formed in the insulating layer so as to pass between adjacent ones of the plurality of sub-pixels, a first electrode disposed on the insulating layer, an emission layer disposed on the first electrode and including a second trench portion extending along the first trench portion, a conductive structure disposed on the second trench portion, and a second electrode disposed on the emission layer and the second trench portion where the conductive structure is disposed.

According to various embodiments of the present disclosure, the second trench portion may include a first trench line extending in a first direction, a second trench line extending in a second direction intersecting with the first direction, and the conductive structure may be disposed in an intersection area where the first trench line and the second trench line intersect with each other.

According to various embodiments of the present disclosure, the second trench portion may include a first trench line extending in a first direction, and a second trench line extending in a second direction intersecting with the first direction, and the conductive structures may be disposed in the first trench line, the second trench line, and an intersection area where the first trench line and the second trench line intersect with each other.

According to various embodiments of the present disclosure, the first trench line and the second trench line may have a first width, and the intersection area may have a second width greater than the first width.

According to various embodiments of the present disclosure, the second trench portion may overlap with the first trench portion in an up and down direction, and be disposed to be spaced apart from the first trench portion.

According to various embodiments of the present disclosure, the second electrode may include a second-first electrode extending from the emission layer to an upper edge of the second trench portion, and a second-second electrode disposed on the second-first electrode, and the conductive structure may be in contact with the second-second electrode.

According to various embodiments of the present disclosure, the second trench portion may include a first portion including a space in which the conductive structure is disposed, and a second portion extending from the first portion toward the substrate.

According to various embodiments of the present disclosure, the first portion of the second trench portion may have a width relatively greater than a width of the second portion, and the second portion may have a width smaller than a width of the conductive structure.

According to various embodiments of the present disclosure, the first portion may have a concave lens shape.

According to various embodiments of the present disclosure, the second trench portion may further include a ferromagnetic pattern disposed within the first trench portion below the second portion.

According to various embodiments of the present disclosure, the second trench portion may include a bottom surface of a first width, sidewall surfaces extending from the bottom surface, and an upper open area having a second width equal to the first width.

According to various embodiments of the present disclosure, the second trench portion may include a bottom surface, sidewall surfaces extending from the bottom surface, and an upper open area, and have a width which becomes smaller as it goes from the upper open area to the bottom surface.

According to various embodiments of the present disclosure, the conductive structure may include a metal material having a high reflectivity.

While the embodiments of the present disclosure have been described in detail with reference to the accompanying drawings, it should be understood by a person skilled in the art that the present disclosure is not necessarily limited to the above embodiments, and the above embodiments can be practiced in various modified forms without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for the purpose of limiting the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of sub-pixels;
an insulating layer disposed on the substrate;
a first trench portion formed in the insulating layer configured to pass between adjacent sub-pixels of the plurality of sub-pixels;
a first electrode disposed on the insulating layer;
an emission layer disposed on the first electrode;
a second trench portion formed in the emission layer, the second trench portion extending along the first trench portion;
a conductive structure disposed in the second trench portion; and
a second electrode disposed on the emission layer and the second trench portion where the conductive structure is disposed.

2. The display apparatus of claim 1, wherein the second trench portion includes:
a first trench line extending in a first direction; and
a second trench line extending in a second direction intersecting with the first direction, and
wherein the conductive structure is disposed in an intersection area where the first trench line and the second trench line intersect with each other.

3. The display apparatus of claim 1, wherein the second trench portion includes:
a first trench line extending in a first direction; and
a second trench line extending in a second direction intersecting with the first direction, and
wherein the conductive structures are disposed in the first trench line, the second trench line, and an intersection area where the first trench line and the second trench line intersect with each other.

4. The display apparatus of claim 2, wherein the first trench line and the second trench line have a first width, and the intersection area has a second width greater than the first width.

5. The display apparatus of claim 1, wherein the second trench portion overlaps with the first trench portion in an up and down direction, and is disposed to be spaced apart from the first trench portion.

6. The display apparatus of claim 1, wherein the second electrode includes:
a second-first electrode extending from the emission layer to an upper edge of the second trench portion; and
a second-second electrode disposed on the second-first electrode, and
wherein the conductive structure is in contact with the second-second electrode.

7. The display apparatus of claim 1, wherein the second trench portion includes:
a first portion including a space in which the conductive structure is disposed, and a second portion extending from the first portion toward the substrate.

8. The display apparatus of claim 7, wherein the first portion of the second trench portion has a first width of the space relatively greater than a second width of the second portion in the same axis, and the second portion has the second width smaller than a width of the conductive structure in the same axis.

9. The display apparatus of claim 7, wherein the first portion includes a concave lens shape.

10. The display apparatus of claim 7, wherein the second trench portion further includes a ferromagnetic pattern disposed within the first trench portion below the second trench portion.

11. The display apparatus of claim 1, wherein the second trench portion includes a bottom surface of a bottom width, sidewall surfaces extending from the bottom surface, and an upper open area having a top width substantially equal to the bottom width.

12. The display apparatus of claim 1, wherein the second trench portion includes a bottom surface, sidewall surfaces extending from the bottom surface, and an upper open area, and
has a width which becomes progressively smaller from the upper open area to the bottom surface.

13. The display apparatus of claim 1, wherein the conductive structure includes a metal material having a high reflectivity.

14. A display apparatus comprising:
a substrate;
an insulating layer disposed on the substrate;
a first trench portion extending into the insulating layer;
a first electrode adjacent to the first trench portion;
an emission layer disposed on the first electrode and the insulating layer;
a second trench portion extending into the emission layer;
a conductive structure located to overlap with the second trench portion in a plan view; and
a second electrode disposed on the emission layer, the second electrode adjacent to the conductive structure.

15. The display apparatus of claim 14, wherein the conductive structure is disposed in the second trench portion and electrically connected to the second electrode.

16. The display apparatus of claim 14, wherein the second trench portion is aligned vertically with the first trench portion.

17. The display apparatus of claim 14, wherein the second trench portion includes a first portion and a second portion between the first portion and the substrate,
wherein the second portion has a width narrower than a width of the first portion, and the conductive structure is disposed within the first portion and positioned above the second portion.

18. The display apparatus of claim 17, further comprising a ferromagnetic pattern disposed within the first trench portion,
wherein the ferromagnetic pattern overlaps the conductive structure in a plan view, and
wherein, during operation, the ferromagnetic pattern generates a magnetic field that attracts the conductive structure to the first portion of the second trench portion solely by magnetic force and without adhesive bonding.

19. The display apparatus of claim 14, wherein the second trench portion includes a first sidewall surface and a second sidewall surface facing the first sidewall surface,
wherein the second electrode extends into the second trench portion and contacts at least one of the first sidewall surface and the second sidewall surface,
wherein the conductive structure is in direct contact with the second electrode,
wherein at least one of the first sidewall surface and the second sidewall surface is inclined such that the distance between the first sidewall surface and the second sidewall surface decreases in a direction toward the substrate.

20. The display apparatus of claim 14, wherein the second trench portion extends from a top surface of the emission layer in a direction toward the substrate, and
wherein the conductive structure is disposed such that at least a portion of the conductive structure protrudes above the top surface of the emission layer.
